(19) United States
(12) Patent Application Publication
(10) Pub. No.: US 2025/0283913 A1
(43) Pub. Date: Sep. 11, 2025

(54) PROBE HOLDER AND INSPECTION METHOD

(71) Applicant: NHK Spring Co., Ltd., Yokohama-shi (JP)

(72) Inventors: Satoshi Shoji, Kanagawa (JP); Ryosuke Yamaguchi, Kanagawa (JP)

(73) Assignee: NHK Spring Co., Ltd., Yokohama-shi (JP)

(21) Appl. No.: 19/074,933

(22) Filed: Mar. 10, 2025

(30) Foreign Application Priority Data
Mar. 11, 2024 (JP) 2024-037562

(51) Int. Cl. G01R 1/073; G01R 35/00

(52) U.S. Cl. CPC G01R 1/07314; G01R 35/00

(57) ABSTRACT

A probe holder holds contact probes each coming in contact with an electrode of a contact target on one end side of the contact probe in a longitudinal direction, and includes: a plurality of holder holes formed in the probe holder and configured to hold the contact probes; an opening portion formed in each of the holder holes on the one end side of the contact probes, the opening portion including a side wall extending in an axial direction of the holder hole from an opening end of the holder hole; and a bottom surface portion provided at an end of the side wall in the axial direction, the end being an end opposite to the opening end.

This application is based upon and claims the benefit of priority of the prior Japanese Patent Application No. 2024-037562, filed on Mar. 11, 2024, the entire contents of which are incorporated herein by reference.

### BACKGROUND

The present disclosure relates to a probe holder and an inspection method.

In the related art, continuity inspection or operating characteristic inspection of an inspection target such as a semiconductor integrated circuit or a liquid crystal display device uses a conductive contact probe that electrically connects the inspection target to a signal processing device including a circuit substrate that outputs an inspection signal (refer to JP 2022-151628 A, for example). Typically, semiconductor wafer level inspections use a probe card in which a plurality of contact probes is disposed. A typical semiconductor finished product inspection uses a socket incorporating a probe block in which a plurality of contact probes is disposed.

### SUMMARY

In the probe holder holding the plurality of contact probes, sliding operations of the contact probes at the time of operations such as inspection gradually causes wear of wall surfaces of holes of the holder through which the contact probes are inserted. The progress of the wear of the hole will change the position of the contact probe in the probe holder, affecting the inspection. On the other hand, it takes time and effort to remove the contact probe from the probe holder and confirm wear of the hole. This has led to a demand for a capability to easily confirm the wear of the holes.

There is a need for a probe holder and an inspection method which are able to easily confirm the wear of the holes.

According to one aspect of the present invention, there is provided a probe holder for holding contact probes each coming in contact with an electrode of a contact target on one end side of the contact probe in a longitudinal direction, the probe holder including: a plurality of holder holes formed in the probe holder and configured to hold the contact probes; an opening portion formed in each of the holder holes on the one end side of the contact probes, the opening portion including a side wall extending in an axial direction of the holder hole from an opening end of the holder hole; and a bottom surface portion provided at an end of the side wall in the axial direction, the end being an end opposite to the opening end.

According to another aspect of the present invention, there is provided an inspection method for inspecting a probe holder configured to hold contact probes each coming in contact with one electrode of a contact target on one end side of the contact probe in a longitudinal direction, the inspection method including inspecting a degree of wear of a holder hole configured to hold each of the contact probes based on a condition of an edge end of a stepped portion in the holder hole, the condition being observed when viewed in an axial direction of the holder hole from an opening end on a side of the holder hole where the one end side of the contact probes extend.

### BRIEF DESCRIPTION OF THE DRAWINGS

FIG. 1 is a perspective view illustrating a configuration of a probe unit according to an embodiment;

FIG. 2 is a partial cross-sectional view illustrating a configuration of a main part of the probe unit according to an embodiment;

FIG. 3 is a cross-sectional view illustrating a configuration of a main part of a probe holder;

FIG. 4(a) and FIG. 4(b) are views for illustrating confirmation of wear of a hole;

FIG. 5 is a cross-sectional view illustrating a configuration of a main part of a probe holder according to a first modification;

FIG. 6 is a cross-sectional view illustrating a configuration of a main part of a probe holder according to a second modification;

FIG. 7 is a cross-sectional view illustrating a configuration of a main part of a probe holder according to a third modification; and

FIG. 8(a) and FIG. 8(b) are views for illustrating confirmation of wear of a hole.

### DETAILED DESCRIPTION

Hereinafter, embodiments for carrying out the present disclosure will be described in detail with reference to the drawings. The present disclosure is not limited to the following embodiments. The drawings used for reference in the following description schematically illustrate shapes, sizes, and positional relationships to the extent to make the description comprehensible. That is, the present disclosure is not limited only to the shapes, sizes, and positional relationships illustrated in each drawing.

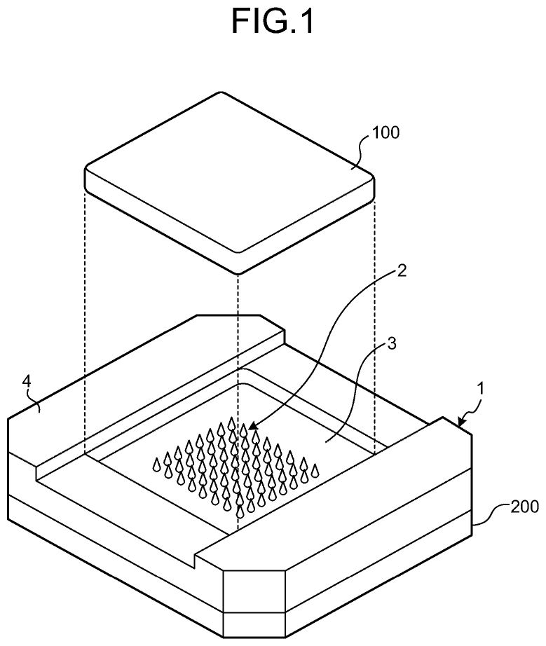

FIG. 1 is a perspective view illustrating a configuration of a probe unit according to an embodiment. A probe unit 1 illustrated in FIG. 1 is a device used in electrical characteristic inspection of a semiconductor integrated circuit 100 being an inspection target, and is a device that provides electrical connection between the semiconductor integrated circuit 100 and a circuit substrate 200 that outputs an inspection signal to the semiconductor integrated circuit 100.

The probe unit 1 includes: contact probes 2 (hereinafter, simply referred to as “probes 2”) having conductivity and coming in contact with electrodes of the semiconductor integrated circuit 100 and the circuit substrate 200, which are two contact objects different from each other at both ends in the longitudinal direction; a probe holder 3 accommodating and holding the probes 2, provided in plurality, according to a predetermined pattern; and a holder member 4 provided around the probe holder 3 to suppress occurrence of positional deviation of the semiconductor integrated circuit 100 coming in contact with the plurality of probes 2 at the time of inspection.

In the present embodiment, the electrode of the semiconductor integrated circuit 100 may be an electrode with a known aspect, such as a ball grid array (BGA) formed using solder, or a lead electrode.

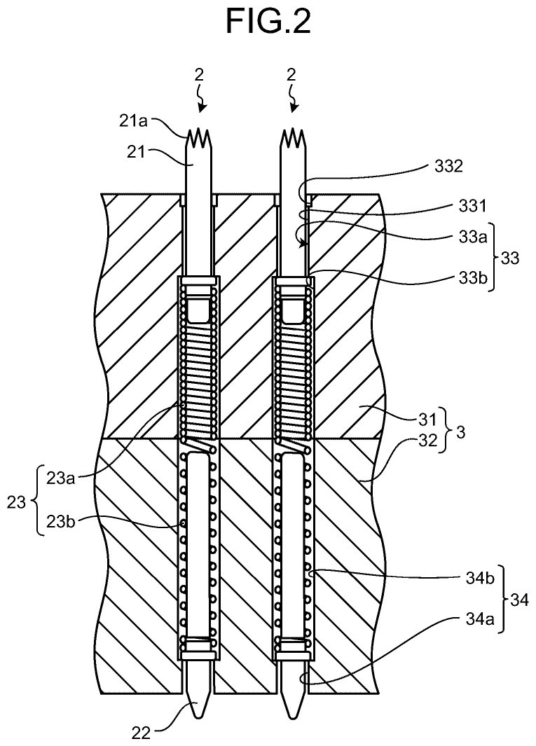

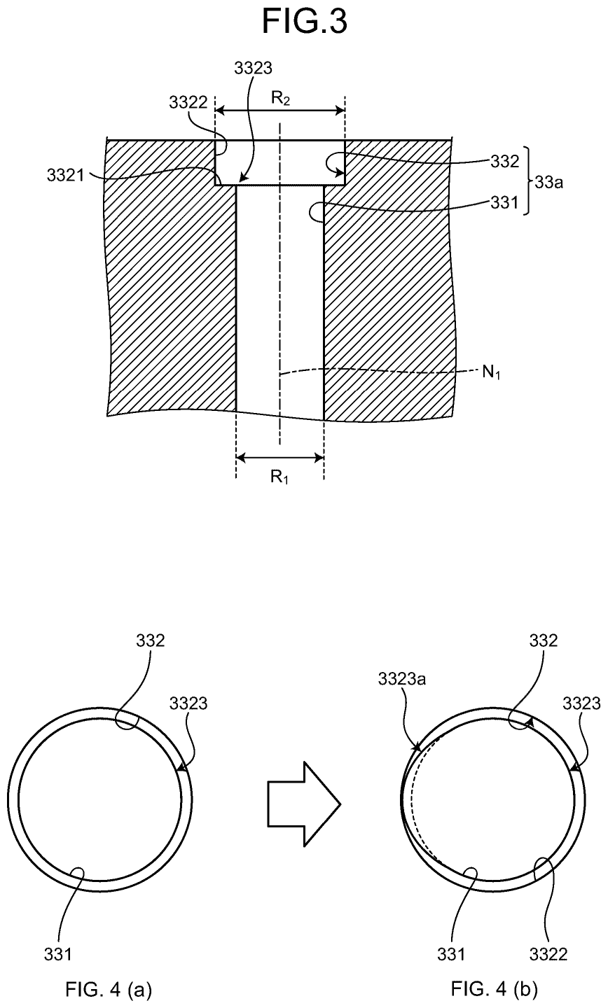

FIG. 2 is a cross-sectional view illustrating a configuration of a main part of the probe unit 1 according to an embodiment. FIG. 3 is a cross-sectional view illustrating a configuration of the main part of the probe holder 3. The probe 2 is formed with a conductive material and includes: a first plunger 21 coming in contact with an electrode of the semiconductor integrated circuit 100 at an inspection of the semiconductor integrated circuit 100; a second plunger 22 coming in contact with an electrode of the circuit substrate 200 equipped with an inspection circuit; and a coil spring 23 provided between the first plunger 21 and the second plunger 22 to couple the first plunger 21 and the second plunger 22 to each other in an extendable/retractable manner. In FIG. 2, the first plunger 21, the second plunger 22, and the coil spring 23 constituting the probe 2 have an identical axis. That is, the central axes of the first plunger 21, the second plunger 22, and the coil spring 23 are located on an identical straight line. The “identical axis” tolerates a deviation due to distortion of individual members, manufacturing errors, and the like. When the semiconductor integrated circuit 100 is brought into contact with the probe 2, expansion and contraction of the coil spring 23 in the axial direction alleviates the impact on the electrode of the semiconductor integrated circuit 100 as well as applying a load onto the semiconductor integrated circuit 100 and the circuit substrate 200.

The first plunger 21 includes a distal end 21a having a tapered tip shape and coming in contact with the electrode of the semiconductor integrated circuit 100. Being movable in the axial direction by the expanding/contracting action of the coil spring 23, the first plunger 21 is biased in the direction of the semiconductor integrated circuit 100 by the elastic force of the coil spring 23 and comes into contact with the electrode of the semiconductor integrated circuit 100.

In the present embodiment, the distal end 21a will be described as an end having a crown shape with a plurality of claws, but may have another shape such as a conical shape or a spherical shape.

The second plunger 22 has a tapered tip shape, and the distal end comes in contact with the electrode of the circuit substrate 200. The second plunger 22 may move in the axial direction by the expanding/contraction action of the coil spring 23, and is biased in the circuit substrate 200 direction by the elastic force of the coil spring 23 and comes into contact with the electrode of the circuit substrate 200.

The coil spring 23 includes: a solid coiling portion 23a being a solidly coiled portion attached to the proximal end side of the first plunger 21; and a sparse coiling portion 23b attached to the proximal end side of the second plunger 22 and coiled at a predetermined interval. The coil spring 23 is formed by coiling one conductive wire, for example.

The end of the solid coiling portion 23a is press-fitted to the proximal end side of the first plunger 21, for example. On the other hand, the end of the sparse coiling portion 23b is press-fitted to the proximal end side of the second plunger 22. The first plunger 21 and the second plunger 22 are joined to the coil spring 23 by coiling force, and/or by soldering. The probe 2 expands and contracts in the axial direction by expansion and contraction of the sparse coiling portion 23b.

The probe holder 3 is formed using an insulating material such as resin, machinable ceramic, or silicon, and is formed by stacking a first member 31 located on the upper surface side and a second member 32 located on the lower surface side in FIG. 2. The first member 31 and the second member 32 each have the same number of holder holes 33 and 34 respectively for accommodating the plurality of probes 2, with the holder holes 33 and 34 accommodating the probes 2 being formed to have their axes aligned with each other. The formation positions of the holder holes 33 and 34 are determined according to the wiring pattern of the semiconductor integrated circuit 100.

The holder holes 33 and 34 each have a stepped hole shape having different diameters in the penetrating direction. That is, the holder hole 33 incudes: a small diameter portion 33a having an opening on an upper end surface of the probe holder 3; and a large diameter portion 33b larger in diameter than the small diameter portion 33a. On the other hand, the holder hole 34 includes: a small diameter portion 34a having an opening on the end surface of the probe holder 3; and a large diameter portion 34b larger in diameter than the small diameter portion 34a. The shapes of the holder holes 33 and 34 are determined according to the configuration of the probe 2 to be accommodated.

Here, the small diameter portion 33a is a portion through which the first plunger 21 is inserted and includes: a hole portion 331 extending from the large diameter portion 33b toward the upper surface side; and an opening portion 332 extending from the hole portion 331 and having an opening on the upper end surface (refer to FIG. 3). The axes of the hole portion 331 and the opening portion 332 are located on an axis N₁ and are aligned with each other. The diameters of the hole portion 331, the opening portion 332, and the large diameter portion 33b satisfy the relationship of the hole portion 331<the opening portion 332<the large diameter portion 33b. Incidentally, regarding the opening portion 332 and the large diameter portion 33b, the diameter of the opening portion 332 may be equal to the diameter of the large diameter portion 33b or may be larger than the diameter of the large diameter portion 33b.

The opening portion 332 is an opening portion having a hole continuous with the hole portion 331 and includes: a bottom surface portion 3321 forming a bottom surface of the opening portion 332; and a side wall portion 3322 having a tubular shape and forming a circumference around the axis N₁. An annular bottom surface formed by the bottom surface portion 3321 is perpendicular to the axis N₁. In the side wall portion 3322, a wall surface extending from the bottom surface portion 3321 toward the opening extends parallel to the axis N₁. Therefore, the opening portion 332 forms a columnar space.

The depth (length in the direction of the axis N₁) of the opening portion 332 is set to dimensions capable of confirming an edge end 3323 of the stepped portion formed by the hole portion 331 and the opening portion 332 by the visual observation using a magnifying glass, a microscope, or the like.

The diameter of the hole on the bottom surface portion 3321, being a diameter R₁ of the hole portion 331, is set to a diameter slightly larger than the diameter of the insertion portion of the hole portion 331 of the first plunger 21. In addition, a diameter R₂ (>R₁) of the opening portion 332 is set based on a diameter ensuring the positional accuracy of the probe 2, for example. The diameter ensuring the positional accuracy is determined based on a wear limit to be set within a range in which the probe may correctly achieve a contact with the inspection target even with a wear in a part or the whole of the bottom surface portion 3321 (edge end 3323) or the hole portion 331.

During the inspection of the semiconductor integrated circuit 100, the coil spring 23 is in a compressed state in the longitudinal direction due to the contact load from the semiconductor integrated circuit 100 and the circuit substrate 200. The inspection signal supplied from the circuit substrate 200 to the semiconductor integrated circuit 100 during the inspection is transferred from the electrode 201 of the circuit substrate 200 to reach a connection electrode 101 of the semiconductor integrated circuit 100 via the second plunger 22, the solid coiling portion 23a, and the first plunger 21 of the probe 2.

In addition, since the tip of the distal end 21a is tapered, even when an oxide film is formed on the surface of the connection electrode 101, it is possible to break the oxide film to allow the tip of the distal end 21a to be brought into direct contact with the connection electrode 101.

When the inspection is repeated, the wall surface of the hole of the holder hole 33 is scraped and worn by actions such as the expansion and contraction operation of the probe 2. FIG. 4(a) and FIG. 4(b) are views for illustrating confirmation of wear of a hole. The example in FIG. 4(a) and FIG. 4(b) are illustrated as an example in which the probe 2 (first plunger 21) slides on a left-side wall surface of the hole portion 331 in the figure, and the wall surface is scraped. At this time, in the state before wear (refer to (a) of FIG. 4(a)), it is possible to clearly identify the entire circumference of the edge end 3323 of the stepped portion formed by the hole portion 331 and the opening portion 332. In contrast, after the wear, a worn portion 3323a of the edge end 3323 of the stepped portion formed by the hole portion 331 and the opening portion 332 is displaced to the side wall portion 3322 side of the opening portion 332 (refer to (b) of FIG. 4(b)). The broken line in FIG. 4(b) indicates the edge end position before the wear. In this manner, the degree of wear of the holder hole 33 may be inspected based on a condition of the edge end (here, the edge end 3323) of the stepped portion, observed when viewed from the opening end in the axial direction of the holder hole. The user may determine the degree of wear of the holder hole by confirming the position not clearly identified.

According to the above-described embodiment, the opening portion 332 corresponding to the counterbore hole is formed on the upper end surface side of the holder hole, and the stepped portion is formed in the vicinity of the opening by the hole portion 331 and the opening portion 332. Therefore, the user may easily confirm the wear of the hole by confirming the edge end of the stepped portion. In contrast, although there is a probe holder in which chamfering is performed or an edge end has a tapered shape, the probe holder does not have a configuration of a stepped portion formed by an inner wall surface and a stepped shape as in the present embodiment, allowing no visual confirmation of the wear of the edge end, making it difficult to identify the wear, unlike the present embodiment. Furthermore, a tapered shape has difficulty in accurately managing and processing the maximum diameter of the shape, making it difficult to form the tapered shape capable of identifying the wear status.

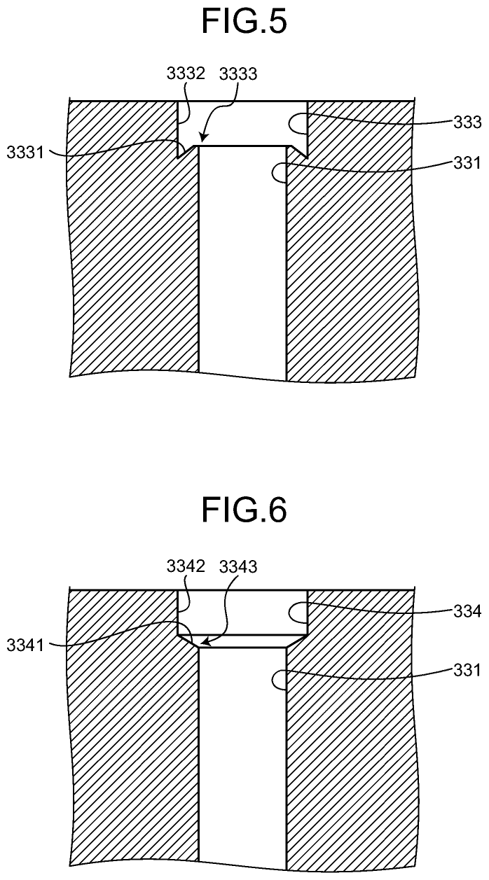

Next, a first modification of the present embodiment will be described with reference to FIG. 5. FIG. 5 is a cross-sectional view illustrating a configuration of a main part of a probe holder according to the first modification. Note that the same components as the components described above in FIG. 2 and the like are denoted by the same reference numerals. The first modification includes an opening portion 333 instead of the opening portion 332 of the holder hole 33 according to the above-described embodiment.

The opening portion 333 has a hole continuous with the hole portion 331 and is formed with: a bottom surface portion 3331 forming a bottom surface of the opening portion 333; and a side wall portion 3332 having a tubular shape and forming a circumference around the axis N₁. The bottom surface formed by the bottom surface portion 3331 has a conical shape inclined with respect to the axis N₁. Specifically, the bottom surface portion 3331 has a conical shape directed toward the opening side as going toward the inner side. Accordingly, the angle of the edge end 3333 of the stepped portion formed by the bottom surface of the bottom surface portion 3331 and the wall surface of the hole portion 331, that is, the angle on the holder constituting portion side (the side opposite to the hollow space side) is an acute angle. The side wall portion 3332 is formed such that a wall surface extending from the bottom surface portion 3331 toward the opening extends parallel to the axis N₁. Therefore, the opening portion 333 forms a columnar space.

The depth (length in the axis N₁ direction) of the opening portion 333 is set to dimensions capable of visually confirming the stepped portion formed by the hole portion 331 and the opening portion 333.

The diameter of the hole of the bottom surface portion 3331, being the diameter of the opening portion 333 (corresponding to the diameter R₂), is similar to the opening portion 332 described above.

In addition, when the inspection is repeated, the wall surface of the hole of the holder hole is scraped and worn by action such as the expansion/contraction operation of the probe 2, and after the wear, the worn portion of the edge end 3333 of the stepped portion formed by the hole portion 331 and the opening portion 333 cannot be clearly identified. The user may determine the degree of wear of the holder hole by confirming the position not clearly identified.

According to the above-described first modification, similarly to the above-described embodiment, the opening portion 333 corresponding to a counterbore hole is formed on the upper end surface side of the holder hole, and the stepped portion is formed in the vicinity of the opening by the hole portion 331 and the opening portion 333. Therefore, the user may easily confirm the wear of the hole by confirming the edge end of the stepped portion.

Furthermore, according to the first modification, since the bottom surface portion is inclined with respect to the axis N₁, changing the degree of reflection of the observation light as compared with the above-described embodiment, making it possible to facilitate observation.

Next, a second modification of the present embodiment will be described with reference to FIG. 6. FIG. 6 is a cross-sectional view illustrating a configuration of a main part of a probe holder according to the second modification. Note that the same components as the components described above in FIG. 2 and the like are denoted by the same reference numerals. The second modification includes an opening portion 334 instead of the opening portion 332 of the holder hole 33 according to the above-described embodiment.

The opening portion 334 has a hole continuous with the hole portion 331 and is formed with: a bottom surface portion 3341 forming a bottom surface of the opening portion 334; and a side wall portion 3342 having a tubular shape and forming a circumference around the axis N₁. The bottom surface formed by the bottom surface portion 3341 has a hollow conical shape inclined with respect to the axis N₁. Specifically, the bottom surface portion 3341 has a conical shape directed toward a side opposite to the opening side (that is, toward the hole portion 331 side) as going toward the inner side. Accordingly, the angle of the edge end 3343 of the stepped portion formed by the bottom surface of the bottom surface portion 3341 and the wall surface of the hole portion 331, that is, the angle on the holder constituting portion side is an obtuse angle. The side wall portion 3342 has a configuration in which a wall surface formed from the bottom surface portion 3341 toward the opening extends parallel to the axis N₁. Therefore, the opening portion 334 forms a columnar space.

The depth (length in the axis N₁ direction) of the opening portion 334 is set to dimensions capable of visually confirming the stepped portion formed by the hole portion 331 and the opening portion 334.

The diameter of the hole of the bottom surface portion 3341, being the diameter of the opening portion 334 (corresponding to the diameter R₂), is similar to the opening portion 332 described above.

In addition, when the inspection is repeated, the wall surface of the hole of the holder hole is scraped and worn by action such as the expansion/contraction operation of the probe 2, and after the wear, the worn portion of the edge end 3343 of the stepped portion formed by the hole portion 331 and the opening portion 334 cannot be clearly identified. The user may determine the degree of wear of the holder hole by confirming the position not clearly identified.

According to the above-described second modification, similarly to the above-described embodiment, the opening portion 334 corresponding to a counterbore hole is formed on the upper end surface side of the holder hole, and the stepped portion is formed in the vicinity of the opening by the hole portion 331 and the opening portion 334. Therefore, the user may easily confirm the wear of the hole by confirming the edge end of the stepped portion.

Furthermore, according to the second modification, since the bottom surface portion is inclined with respect to the axis N₁, changing the degree of reflection of the observation light as compared with the above-described embodiment, making it possible to facilitate observation.

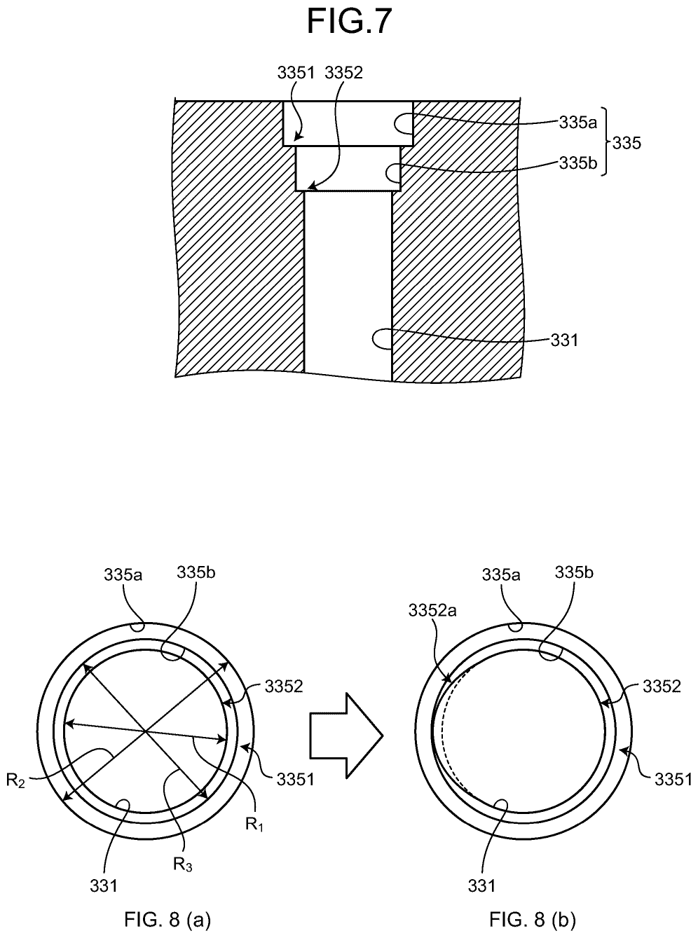

Next, a third modification of the present embodiment will be described with reference to FIGS. 7 and 8. FIG. 7 is a cross-sectional view illustrating a configuration of a main part of a probe holder according to the third modification. Note that the same components as the components described above in FIG. 2 and the like are denoted by the same reference numerals. The third modification includes an opening portion 335 instead of the opening portion 332 of the holder hole 33 according to the above-described embodiment.

The opening portion 335 includes: a first opening portion 335a provided on the upper end surface (opening end) side; and a second opening portion 335b extending from the first opening portion 335a to the side opposite to the upper end surface side and continuing to the hole portion 331. The first opening portion 335a and the second opening portion 335b each include a side surface portion extending in the axial direction and a bottom surface portion in which a hole is formed. The bottom surface portion may adopt the configurations of the first and second modifications.

The depth of the opening portion 335 is set to dimensions capable of visually confirming the stepped portion of the opening portion 335 and the stepped portion formed by the hole portion 331 and the opening portion 335.

The diameter formed by the side wall portion of the first opening portion 335a is similar to the diameter R₂ of the opening portion 332 (refer to FIG. 3). In addition, a diameter R₃ which is a diameter formed by the side wall portion of the second opening portion 335b, being a diameter formed by the hole of the bottom surface portion of the first opening, is set to be slightly larger than the diameter R₁ of the hole portion 331 and smaller than the diameter (diameter R₂) of the first opening portion 335a. For example, the diameter R₂ is set based on an amount of wear that requires replacement of the probe holder. Moreover, for example, the diameter R₃ is set based on an amount of wear that encourages replacement of the probe holder at the next use. The diameter formed by the hole of the bottom surface portion of the second opening portion 335b is similar to the diameter R₁ of the hole portion 331 (refer to FIG. 3).

When the inspection is repeated, the wall surface of the hole of the holder hole is scraped and worn by actions such as the expansion and contraction operation of the probe 2. FIG. 8(a) and FIG. 8(b) are views for illustrating confirmation of wear of a hole. The example in FIG. 8(a) and FIG. 8(b) are illustrated as an example in which the probe 2 (first plunger 21) slides on a left-side wall surface of the hole portion 331 in the figure, and the wall surface is scraped. At this time, in a state before wear (refer to FIG. 8(a)), it is possible to clearly identify the entire circumference of the edge end 3351 of the stepped portion formed by the first opening portion 335a and the second opening portion 335b and the entire circumference of the edge end 3352 of the stepped portion formed by the second opening portion 335b and the hole portion 331. In contrast, after the wear, a worn portion 3352a of the edge end 3351 is displaced to the side wall portion side of the second opening portion 335b (refer to FIG. 8(b)). The broken line in FIG. 8(b) indicates the edge end position before wear. The user may determine the degree of wear of the holder hole by confirming the position not clearly identified. In third modification, the state where a part of the edge end 3351 is flush with the wall surface of the first opening portion 335a may be used as an indicator for replacing the probe holder at the next use.

According to the above-described third modification, similarly to the above-described embodiment, the opening portion 335 corresponding to a counterbore hole is formed on the upper end surface side of the holder hole, and the stepped portion is formed in the vicinity of the opening by the hole portion 331 and the opening portion 335. Therefore, the user may easily confirm the wear of the hole by confirming the edge end of the stepped portion.

Furthermore, according to the third modification, the two stepped portions are formed in the opening portion so as to allow the user to grasp the degree of wear in two stages. Therefore, the degree of wear and the replacement timing may be grasped more finely as compared with the embodiment.

Although the embodiments for carrying out the present disclosure have been described so far, the present disclosure should not be limited only by the above-described embodiments. For example, the above-described embodiment and modifications have described an example of grasping the wear amount by visually confirming the wear of the edge end. However, it is also allowable to image the opening of the hole in the axial direction, calculate the wear amount of the edge end by image processing, and determine whether the probe holder need replacement.

As described above, the probe holder and the inspection method according to the present disclosure are useful for easily confirming wear of the hole.

According to the present disclosure, it is possible to easily confirm the wear of the holes.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiments have been described in detail, it should be understood that the various changes, substitutions, and alterations could be made hereto without departing from the spirit and scope of the disclosure.

What is claimed is:

1. A probe holder for holding contact probes each coming in contact with an electrode of a contact target on one end side of the contact probe in a longitudinal direction, the probe holder comprising:
a plurality of holder holes formed in the probe holder and configured to hold the contact probes;
an opening portion formed in each of the holder holes on the one end side of the contact probes, the opening portion including
a side wall extending in an axial direction of the holder hole from an opening end of the holder hole; and
a bottom surface portion provided at an end of the side wall in the axial direction, the end being an end opposite to the opening end.

2. The probe holder according to claim 1, wherein the bottom surface portion is formed by a plane perpendicular to the axial direction.

3. The probe holder according to claim 1, wherein the bottom surface portion is formed by a plane inclined with respect to the axial direction.

4. The probe holder according to claim 1, wherein
the opening portion includes:
a first opening portion extending in the axial direction from the opening end of the holder hole; and
a second opening portion extending from the first opening portion to a side opposite to the opening end side,
the first opening portion includes:
a first side wall extending in the axial direction of the holder hole from the opening end; and
a first bottom surface portion having a hollow plate shape and extending inward from an end of the first side wall in the axial direction, the end being an end opposite to the opening end, and
the second opening portion includes:
a second side wall extending in the axial direction of the holder hole from an opening end formed by the first bottom surface portion; and
a second bottom surface portion having a hollow plate shape and extending inward from an end of the second side wall in the axial direction, the end being an end opposite to the opening end of the first bottom surface portion.

5. The probe holder according to claim 1, wherein
a hole is formed in the bottom surface portion, and
a diameter of the hole of the bottom surface portion is set based on a wear limit of the holder hole.

6. An inspection method for inspecting a probe holder configured to hold contact probes each coming in contact with one electrode of a contact target on one end side of the contact probe in a longitudinal direction, the inspection method comprising
inspecting a degree of wear of a holder hole configured to hold each of the contact probes based on a condition of an edge end of a stepped portion in the holder hole, the condition being observed when viewed in an axial direction of the holder hole from an opening end on a side of the holder hole where the one end side of the contact probes extend.
